(19) United States
(12) Patent Application Publication
(10) Pub. No.: US 2025/0110409 A1
(43) Pub. Date: Apr. 3, 2025

(54) SPIN-ON ADHESION PROMOTER COMPOSITION AND METHOD FOR HIGH NUMERICAL APERTURE EXTREME ULTRAVIOLET LITHOGRAPHY

(71) Applicant: International Business Machines Corporation, Armonk, NY (US)

(72) Inventors: Dario Goldfarb, Lake Carmel, NY (US); Christopher M. Bottoms, Albany, NY (US); Nicholas Latham, Albany, NY (US); Yasiel Cabrera, Albany, NY (US)

(21) Appl. No.: 18/479,181

(22) Filed: Oct. 2, 2023

(51) Int. Cl. G03F 7/11; G03F 7/105; G03F 7/16; G03F 7/20

(52) U.S. Cl. CPC G03F 7/11; G03F 7/105; G03F 7/162; G03F 7/2004

(57) ABSTRACT

An adhesion promoter composition is provided and includes a molecular adhesion promoter, a casting solvent and a self-immolative polymeric matrix.

### BACKGROUND

The present invention generally relates to fabrication methods and resulting structures for semiconductor devices. More specifically, the present invention relates to a spin-on adhesion promoter composition and method for high numeral aperture (NA) extreme ultraviolet (EUV) lithography.

Photolithography is used as part of semiconductor manufacturing processes to delineate patterns representing particular device or circuit structures on a surface of a silicon wafer. This pattern is made with photoresist, which protects the underlying substrate from subsequent processing. The physical or electrical characteristics of the unprotected surfaces are altered by process steps such as etch, deposition, ion implantation, sputtering, etc. This cycle is repeated many times.

One type of photolithography is EUV lithography. EUV lithography is a next-generation lithography technology using an EUV wavelength, currently expected to be 13.5 nm. EUV allows for feature patterning at smaller dimensions than other conventional photolithographic processes. The use of EUV lithography typically requires improved molecular primer chemistry to provide sufficient adhesion and a residue-free underlayer to the hardmask-EUV resist interface. The use of EUV enabling a smaller feature width decreases the area available for the patterned photoresist structure to adhere to the underlying substrate. Therefore, the adhesion strength between the pattern material and the underlying substrate is weakened.

### SUMMARY

Embodiments of the invention are directed to an adhesion promoter composition. A non-limiting example of the adhesion promoter composition includes a molecular adhesion promoter, a casting solvent and a self-immolative polymeric matrix.

Embodiments of the present invention are directed to an adhesion promoter composition. A non-limiting example of the adhesion promoter composition includes an organosilicon or organogermanium compound in which organic substituents on silicon or germanium atoms are phenyl substituents, a self-immolative organic polymeric compound and a casting solvent.

Embodiments of the present invention are directed to a method of adhesion promoter formation on a surface. A non-limiting example of the method of adhesion promoter formation on a surface includes combining a self-immolative organic polymeric compound, a casting solvent and an organosilicon or organogermanium compound in which organic substituents on silicon or germanium atoms are phenyl substituents to form a liquid adhesion promoter composition. The method further includes spin coating the liquid adhesion promoter composition on the surface, evaporating liquid from the liquid adhesion promoter composition to convert the liquid adhesion promoter composition into a solid adhesion promoter composition, baking at a first temperature to decompose the self-immolative organic polymeric compound to leave a continuous film of the organosilicon or organogermanium compound on the surface and baking at a second temperature such that the organosilicon or organogermanium compound reacts with the surface to form an adhesion promoter on the surface.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a flow diagram illustrating a method of adhesion promoter formation on a surface in accordance with one or more embodiments of the present invention;

FIG. 2 is a flow diagram illustrating a resist patterning method in accordance with one or more embodiments of the present invention; and

FIG. 3 is a graphical depiction of the methods of FIGS. 1 and 2 in sequence in accordance with one or more embodiments of the present invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, a typical semiconductor manufacturing process is mechanical or chemical surface preparation followed by hexamethyldisilazane (HMDS) priming. The HDMS priming is typically followed by a resist apply, which is followed by a pattern resist and subsequent processing. This cycle can be repeated many times until device fabrication is completed. The HDMS priming operation is performed to apply HMDS as a photoresist adhesion promoter. Photoresist adhesion promoters, such as HMDS, are typically utilized to enhance/increase adhesion between a photoresist material and an underlying layer as HMDS binds to oxygen atoms of the substrate via its silicon atoms under the removal of ammonia. The resulting non-polar methyl groups create a hydrophobic surface that promotes adhesion.

A problem with the use of HDMS is that it can be difficult to obtain a desired yield of the resulting molecular structures. This is because underexposure during EUV lithography does not generate a sufficient number of the molecular structures. On the other hand, overexposure generates excessive numbers of the molecular structures but they tend to be structurally unsound due to the vertical height of the molecular structures relative to the underlying substrate (i.e., the molecular structures possess a substantial aspect ratio). In fact, it has been found that there is no exposure window which lends itself to a successful yield.

A solution to the problems associated with HDMS was proposed in which an adhesion promoter layer was formed with organic planarization layer (OPL) material. This layer was around 5 nm thick and served as an adhesion promoter between an underlying substrate of a transparent oxide and an overlying resist layer due to the chemical compatibility between the OPL and the transparent oxide and due to the chemical compatibility between the OPL and the resist layer. In operation, however, it was found that, although the OPL serves as an adhesion layer, the OPL requires an additional open step prior to further etch transfer and this additional open step removes resist material. Meanwhile, patterning with high NA EUV already requires a reduced resist thickness budget in order to maintain a feature aspect ratio, which lead to further compromise of the resist thickness budget.

It was then found that OPL could be replaced by a molecular spin-on adhesion promoter with highly uniform coating capability across a 300 mm wafer that has a siloxane based chemistry, which is reactive with Si—O—Si or Si—OH surface groups, and does not require an additional open step for etch transfer. This siloxane based molecular spin-on adhesion promoter also has the benefit of being only about ˜1 nm thick. Thus, for high NA EUV, it is possible to provide features having full (i.e., about ˜28 nm thickness) resist.

A further problem was that the siloxane based molecular spin-on adhesion promoter, such as hexaphenylcyclotrisiloxane (HPCTS), when mixed with a casting solvent and spun onto a 300 mm wafer, led to high-yield structures in the middle of the wafer that degraded outwardly with center-to-edge variability.

A need therefore remains for a siloxane based molecular spin-on adhesion promoter that is molecularly thin and does not exhibit center-to-edge variability during spin-on operations.

Turning now to an overview of the aspects of the invention, one or more embodiments of the invention address the above-described shortcomings of the prior art by providing an adhesion promoter composition that includes a molecular adhesion promoter, a casting solvent and a self-immolative polymeric matrix. In greater detail, the adhesion promoter composition includes an organosilicon or organogermanium compound in which organic substituents on silicon or germanium atoms are phenyl substituents, at least one self-immolative organic polymeric compound, at least one optional catalyst and at least one casting solvent.

The above-described aspects of the invention address the shortcomings of the prior art by providing for a spin-on adhesion promoter composition that includes a self-immolative polymeric matrix, an optional catalyst, a molecular adhesion promoter and a casting solvent. This composition is molecularly thin, does not exhibit center-to-edge variability during spin-on operations and provides for a molecularly thin and uniform coating.

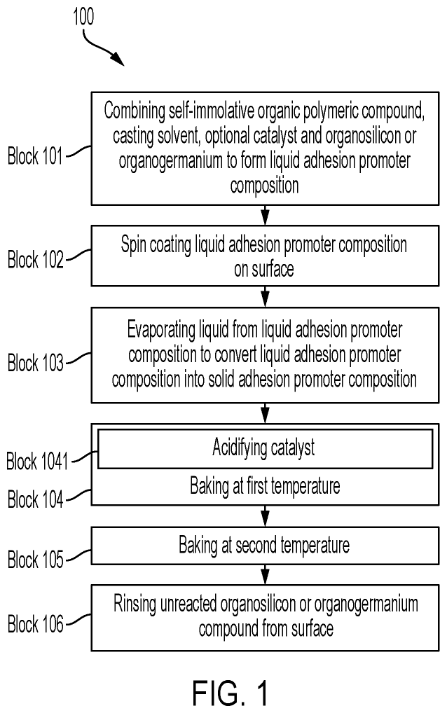

Turning now to a more detailed description of aspects of the present invention, FIG. 1 depicts a method 100 of adhesion promoter formation on a surface, such as a surface of a transparent oxide layer. As shown in FIG. 1, the method 100 initially includes combining a self-immolative organic polymeric compound, a casting solvent, an optional catalyst and an organosilicon or organogermanium compound in which organic substituents on silicon or germanium atoms are phenyl substituents to form a liquid adhesion promoter composition (block 101). In addition, the method 100 further includes spin coating the liquid adhesion promoter composition on the surface (block 102), evaporating liquid from the liquid adhesion promoter composition to convert the liquid adhesion promoter composition into a solid adhesion promoter composition (block 103), baking at a first temperature to decompose the self-immolative organic polymeric compound to leave a continuous film of the organosilicon or organogermanium compound on the surface (block 104) and baking at a second temperature such that the organosilicon or organogermanium compound reacts with the surface to form an adhesion promoter on the surface (block 105). The method 100 can also include rinsing unreacted organosilicon or organogermanium compound from the surface (block 106).

In those cases in which the liquid adhesion promoter composition includes the optional catalyst, the baking of block 104 can include acidifying the catalyst (block 1041) and the first temperature can be in a range of 90-180° C., inclusive, or in a range of 120-160° C., inclusive. In those cases in which the liquid adhesion promoter composition does not include the optional catalyst, the first temperature can be in a range of 140-220° C., inclusive, or in a range of 160-200° C., inclusive. The process of acidifying the catalyst includes, for example, thermally decomposing a thermal acid generator (TAG), to yield a thermally generated acid that acts as an acidic (acidified) catalyst. An example of a suitable TAG is para-nitrobenzyl tosylate (pNBT) which thermally decomposes starting at around 110 C generating an acidic species (tosylic acid).

The self-immolative organic polymeric compound can be provided such that it decomposes into its organic monomeric constituent elements in the baking of block 104 with acidified catalyst at the first temperature in a range of 90-180° C., inclusive, with a narrow and specific range of 120-160° C., inclusive. For example, a 110 nm thick film of polyphthalaldehyde (an organic polymer) decomposes at 140° C. with acidified catalyst generating phthalaldehyde (an organic monomer) and reducing its thickness by half (55 nm) after 25 seconds of baking. Complete polyphthalaldehyde film decomposition and phthalaldehyde monomer volatilization is achieved after 60 seconds.

The self-immolative organic polymeric compound can be provided such that it decomposes into its organic monomeric constituent elements in the baking of block 104 without the catalyst at the first temperature in a range of 140-220° C., inclusive, with a narrow and specific range of 160-200° C., inclusive. For example, a 100 nm thick film of polyphthalaldehyde (an organic polymer) decomposes at 180° C. without the catalyst generating phthalaldehyde (an organic monomer) and reducing its thickness by half (50 nm) after two minutes of baking. Complete decomposition of a 120 nm thick polyphthalaldehyde film and phthalaldehyde monomer volatilization is achieved at 200° C. after 60 seconds.

In accordance with one or more embodiments of the present invention, the organosilicon or organogermanium compound can include at least one of:
(a) a cyclic compound having the formula:

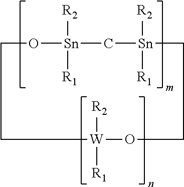

(b) a non-cyclic compound having the formula:

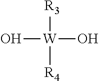

wherein:
R1 and R2 each independently represents a non-photoactive phenyl, a photoactive phenyl or a C1-C4 alkyl,
R3 represents a non-photoactive phenyl,
R4 represents a photoactive phenyl,
W represents Si or Ge,
n represents an integer of value greater than 1, and
m represents an integer between 0 and 1.

Cyclic compounds having the aforementioned formula can be:
Hexaphenylcyclotrisiloxane (“HPCTS”), wherein m is 0, n is 3, W is Si and R₁ and R₂ are Phenyl, e.g.,

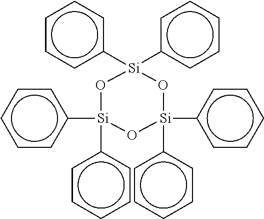

Octaphenylcyclotetrasiloxane, wherein m is 0, n is 4, W is Si and R₁ and R₂ are Phenyl, e.g.,

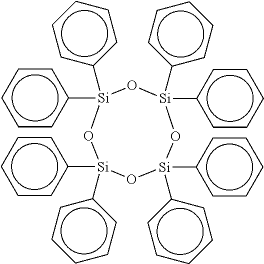

2,4,6-Trimethyl-2,4,6-triphenylcyclotrisiloxane, wherein m is 0, n is 3, W is Si and R₁ and R₂ are Phenyl or Methyl, e.g.,

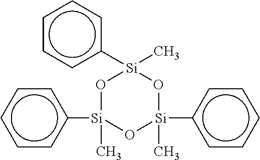

Dodecamethylcyclohexasiloxane, wherein m is 0, n is 6, W is Si and R₁ and R₂ are Methyl, e.g.,

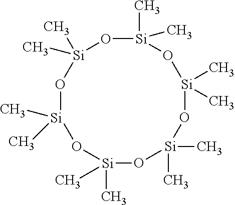

Octaphenyltetrasiloxane (“OPCTS”) or 1,1,3,3,5,5,7,7 Octaphenyl-4,6,8-trioxa-1,3-distanna-5,7-disilacyclooctane, wherein m is 1, n is 2, W is Si and R₁ and R₂ are Phenyl, e.g.,

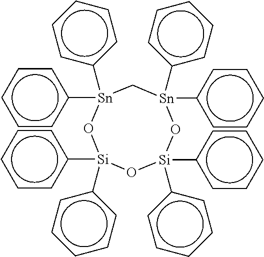

1,1,3,3,5,5,7,7,9,9-Decaphenyl-4,6,8,10-tetraoxa-1,3-distanna-5,7,9-trisilacyclodecane, wherein m is 1, n is 3, W is Si and R₁ and R₂ are Phenyl, e.g.,

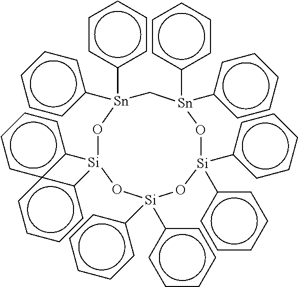

1,1,3,3,5,5,7,7,9,9,11,11-Dodecaphenyl-4,6,8,10,12-pentaoxa-1,3-distanna-5,7,9,11-tetrasilacyclododecane, wherein m is 1, n is 4, W is Si and R₁ and R₂ are Phenyl, e.g.,

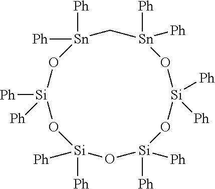 [SMILES: c1ccc([Si]2(c3ccccc3)O[Si](c3ccccc3)(c3ccccc3)O[Si](c3ccccc3)(c3ccccc3)[O][Sn]([c]3ccccc3)([c]3ccccc3)[CH2][Sn]([c]3ccccc3)([c]3ccccc3)[O][Si](c3ccccc3)(c3ccccc3)O2)cc1]

1,1,3,3-Tetraphenyl-5,5-di-tert-butyl-4,6-dioxa-1,3-distanna-5-silacyclohexane, wherein m is 1, n is 1, W is Silicon and R₁ and R₂ are Phenyl or tert-Butyl, e.g.,

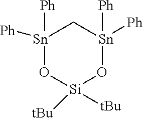 [SMILES: CC(C)(C)[Si]1(C(C)(C)C)[O][Sn]([c]2ccccc2)([c]2ccccc2)[CH2][Sn]([c]2ccccc2)([c]2ccccc2)[O]1]

1,1,3,3-Tetraphenyl-5,5-di-tert-butyl-4,6-dioxa-1,3-distanna-5-germacyclohexane, wherein m is 1, n is 1, W is Ge and R₁ and R₂ are Phenyl or tert-Butyl, e.g.,

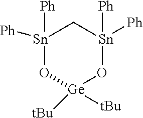

Triphenylsulfonium 4-phenylsulfonate-2,2,4,6,6-pentaphenyl-cyclotrisiloxane, wherein m is 0, n is 3, W is Si and R₁ and R₂ are Phenyl or photoactive Phenyl, e.g.,

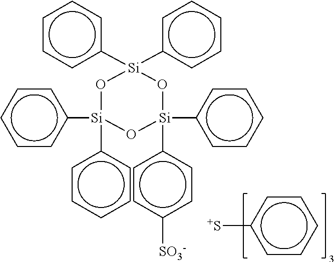

Triphenylsulfonium 4-phenylsulfonate 2,2,4,6,6,8,8-heptaphenyl-cyclotetrasiloxane, wherein m is 0, n is 4, W is Si and R₁ and R₂ are Phenyl or photoactive Phenyl, e.g.,

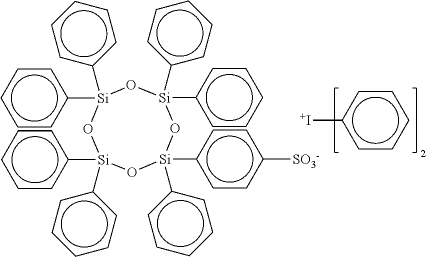

Triphenylsulfonium 5-phenylsulfonate-1,1,3,3,5,7,7,9,9-nonaphenyl-4,6,8,10-tetraoxa-1,3-distanna-5,7,9-trisilacyclodecane, wherein m is 1, n is 3, W is Si and R₁ and R₂ are Phenyl or photoactive Phenyl, e.g.,

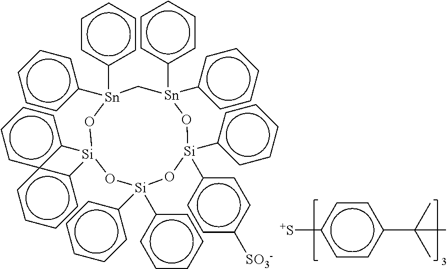

Non-cyclic compounds having the aforementioned formula can be:
TPS phenylsulfonate phenylsilanediol (“TPS-PSPS”); DPI phenylsulfonate phenylsilanediol (DPI-PSPS), wherein W is Si and R₁ and R₂ are Phenyl or photoactive Phenyl, e.g.,

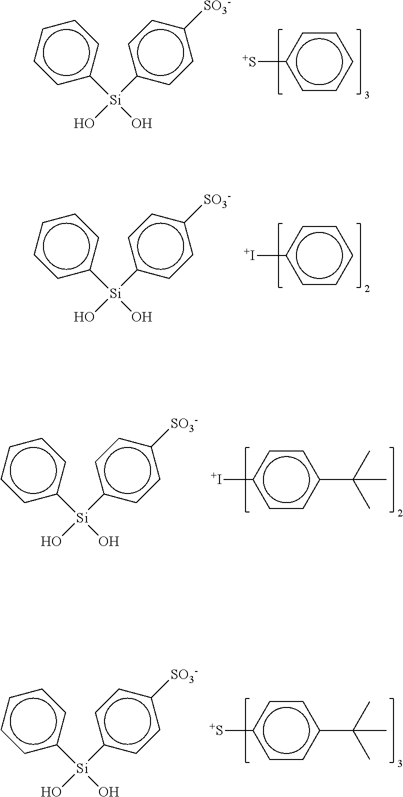

The adhesion promoter composition can include at least one of the aforementioned compounds or one or more of the following compounds. For example, the adhesion promoter composition can include a mixture of the compounds HPCTS and OPCTS. Additionally, the aforementioned compounds may be engineered to be non-photoactive (e.g., HPCTS and OPCTS) or photoactive (e.g., triphenylsulfonium 4-phenylsulfonate-2,2,4,6,6-pentaphenyl-cyclotrisiloxane and TPS-PSPS) so that the compounds will react to light in photoresist semiconductor applications.

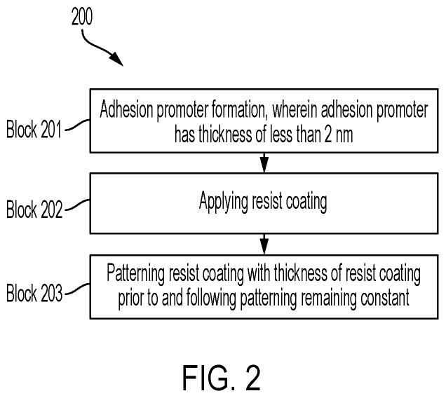

With continued reference to FIG. 1 and with additional reference to FIG. 2, the method 100 of FIG. 1 can be provided as a preparation for a resist patterning method 200. As shown in FIG. 2, the resist patterning method 200 includes the method 100 of adhesion promoter formation on the surface as described above, wherein the adhesion promoter has a thickness of less than 2 nm (block 201), applying a resist coating on the adhesion promoter on the surface (block 202) and patterning the resist coating to a depth of the adhesion promoter (block 203) with a thickness of the resist coating prior to and following the patterning of block 203 remaining constant.

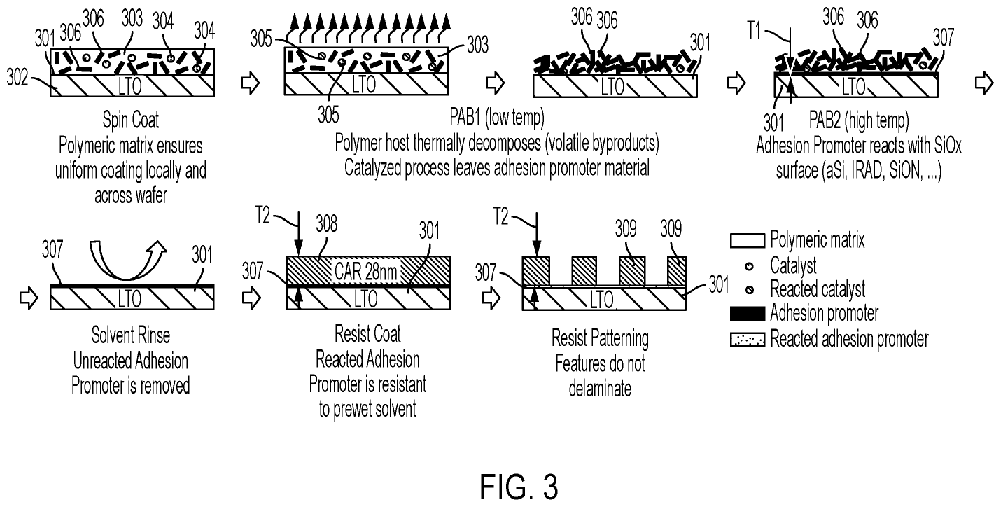

With continued reference to FIGS. 1 and 2 and with additional reference to FIG. 3, a graphical depiction of the method 100 and the method 200 is provided and relates to the case in which the liquid adhesion promoter composition includes the optional catalyst (this is done for purposes of clarity and brevity and should not be interpreted as limited the scope of the description or the claims in any way). As shown in FIG. 3, the liquid adhesion promoter composition is applied to a surface 301 of a transparent oxide layer 302 by spin coating. Here, the presence of a polymeric matrix 303 of the self-immolative organic polymeric compound ensures uniform coating locally and across the wafer (i.e., across the surface 301 of the transparent oxide 302). Following the spin coating, a first baking operation is conducted at a relatively low first temperature whereby the catalyst 304 acidifies and, in the presence of the acidified catalyst 305, polymeric matrix 303 of the self-immolative organic polymeric compound thermally decomposes into volatile byproducts and leaves adhesion promoter material 306 on the surface 301. Subsequently, a second baking operation is conducted at a relatively high temperature whereby the adhesion promoter material 306 reacts with the surface 301 to form a layer of reacted adhesion promoter 307. The layer of the reacted adhesion promoter 307 can have a thickness T1 of less than about 2 nm or about 1-1.5 nm. Unreacted adhesion promoter material 306 is then rinsed by a solvent. Following the rinsing, a resist coating 308 is applied to the layer of the reacted adhesion promoter 307 and is subsequently patterned into features 309. As noted above and as shown in FIG. 3, a thickness T2 of the resist coating 308 prior to and following the patterning remains constant.

As an example of a formulation composition and processing method: a liquid formulation containing 4% wt cyclic polyphthalaldehyde (cPPA), 2% wt octaphenylcyclotetrasiloxane (OPCTS), 0.13% wt para-nitrobenzyltosylate (pNBT) and 93.87% wt cyclohexanone is spun at 1000 rpm for 30 seconds on a silicon wafer and baked on a hotplate at 140° C. for 3 minutes followed by a second bake at 180° C. for 3 minutes. The silicon wafer is then rinsed with cyclohexanone to yield an adhesion promoter layer of 1-1.5 nm thickness above the silicon wafer surface.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having.” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. An adhesion promoter composition, comprising:
a molecular adhesion promoter;
a casting solvent; and
a self-immolative polymeric matrix.

2. The adhesion promoter composition according to claim 1, wherein:
the adhesion promoter composition further comprises a catalyst, and,
with the catalyst being acidified, the self-immolative polymeric matrix decomposes into organic monomeric constituents in a 90-180° C. bake.

3. The adhesion promoter composition according to claim 1, wherein:
the adhesion promoter composition further comprises a catalyst, and,
with the catalyst being acidified, the self-immolative polymeric matrix decomposes into organic monomeric constituents in a 120-160° C. bake.

4. The adhesion promoter composition according to claim 1, wherein self-immolative polymeric matrix decomposes into organic monomeric constituents in a 140-220° C. bake.

5. The adhesion promoter composition according to claim 1, wherein self-immolative polymeric matrix decomposes into organic monomeric constituents in a 160-200° C. bake.

6. An adhesion promoter composition, comprising:
an organosilicon or organogermanium compound in which organic substituents on silicon or germanium atoms are phenyl substituents;
a self-immolative organic polymeric compound; and
a casting solvent.

7. The adhesion promoter composition according to claim 6, wherein the organosilicon or organogermanium compound is one of (a) and (b) as follows:
(a) a cyclic compound having a formula: 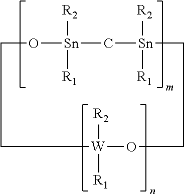
(b) a non-cyclic compound having a formula: 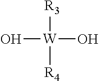
wherein:
R1 and R2 each independently represents a non-photoactive phenyl, a photoactive phenyl or a C1-C4 alkyl,
R3 represents a non-photoactive phenyl,
R4 represents a photoactive phenyl,
W represents Si or Ge,
n represents an integer of value greater than 1, and
m represents an integer between 0 and 1.

8. The adhesion promoter composition according to claim 6, wherein:
the adhesion promoter composition further comprises a catalyst, and,
with the catalyst being acidified, the self-immolative organic polymeric compound decomposes into organic monomeric constituents in a 90-180° C. bake.

9. The adhesion promoter composition according to claim 6, wherein:
the adhesion promoter composition further comprises a catalyst, and,
with the catalyst being acidified, the self-immolative organic polymeric compound decomposes into organic monomeric constituents in a 120-160° C. bake.

10. The adhesion promoter composition according to claim 6, wherein the self-immolative organic polymeric compound decomposes into organic monomeric constituents in a 140-220° C. bake.

11. The adhesion promoter composition according to claim 6, wherein the self-immolative organic polymeric compound decomposes into organic monomeric constituents in a 160-200° C. bake.

12. A method of adhesion promoter formation on a surface, the method comprising:
combining a self-immolative organic polymeric compound, a casting solvent and an organosilicon or organogermanium compound in which organic substituents on silicon or germanium atoms are phenyl substituents to form a liquid adhesion promoter composition;
spin coating the liquid adhesion promoter composition on the surface;
evaporating liquid from the liquid adhesion promoter composition to convert the liquid adhesion promoter composition into a solid adhesion promoter composition;
baking at a first temperature to decompose the self-immolative organic polymeric compound to leave a continuous film of the organosilicon or organogermanium compound on the surface; and
baking at a second temperature such that the organosilicon or organogermanium compound reacts with the surface to form an adhesion promoter on the surface.

13. The method according to claim 12, wherein the organosilicon or organogermanium compound is one of (a) and (b) as follows:
(a) a cyclic compound having a formula: 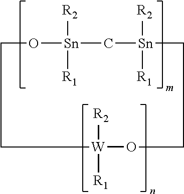
(b) a non-cyclic compound having a formula: 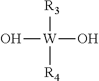
wherein:
R1 and R2 each independently represents a non-photoactive phenyl, a photoactive phenyl or a C1-C4 alkyl,
R3 represents a non-photoactive phenyl,
R4 represents a photoactive phenyl,
W represents Si or Ge,
n represents an integer of value greater than 1, and
m represents an integer between 0 and 1.

14. The method according to claim 12, further comprising rinsing unreacted organosilicon or organogermanium compound from the surface.

15. The method according to claim 12, wherein:
the combining comprises combining the self-immolative organic polymeric compound, the casting solvent and the organosilicon or organogermanium compound with a catalyst, and
the method further comprises acidifying the catalyst and the first temperature is 90-180° C.

16. The method according to claim 12, wherein:
the combining comprises combining the self-immolative organic polymeric compound, the casting solvent and the organosilicon or organogermanium compound with a catalyst, and
the method further comprises acidifying the catalyst and the first temperature is 120-160° C.

17. The method according to claim 12, wherein the first temperature is 140-220° C.

18. The method according to claim 12, wherein the first temperature is 160-200° C.

19. A resist patterning method, comprising:
the method of adhesion promoter formation on the surface according to claim 12, wherein the adhesion promoter has a thickness of less than 2 nm;
applying a resist coating on the adhesion promoter on the surface; and
patterning the resist coating to a depth of the adhesion promoter.

20. The resist patterning method according to claim 19, wherein a thickness of the resist coating prior to and following the patterning is constant.
